(19) United States
(12) Patent Application Publication
(10) Pub. No.: US 2025/0301703 A1
(43) Pub. Date: Sep. 25, 2025

(54) CHANNEL STRUCTURES IN SEMICONDUCTOR DEVICES

(71) Applicant: Taiwan Semiconductor Manufacturing Company, Ltd., Hsinchu (TW)

(72) Inventors: Yu-Wei LU, Taipei City (TW); Ding-Kang SHIH, New Taipei City (TW); Yi-Lun CHEN, Taichung City (TW); Kenichi SANO, Hsinchu (TW)

(73) Assignee: Taiwan Semiconductor Manufacturing Company, Ltd., Hsinchu (TW)

(21) Appl. No.: 18/614,098

(22) Filed: Mar. 22, 2024

(51) Int. Cl. H01L 29/423; H01L 21/8234; H01L 27/088; H01L 29/06; H01L 29/66; H01L 29/775; H01L 29/78; H01L 29/786

(52) U.S. Cl. CPC H10D 30/6735; H10D 30/014; H10D 30/43; H10D 30/6757; H10D 30/797; H10D 62/121; H10D 84/0128; H10D 84/038; H10D 84/83

(57) ABSTRACT

The present disclosure provides nanostructured channel structures of a semiconductor device and fabricating methods thereof. The method can include forming a superlattice structure with a first nanostructured layer and a second nanostructured layer on a fin base, forming a polysilicon structure on the superlattice structure, removing the second nanostructured layer to form a first gate opening, removing the polysilicon structure to form a second gate opening, forming a capping layer on the first nanostructured layer, modifying the first nanostructured layer to form a nanostructured channel layer having an undoped semiconductor region and a doped semiconductor region surrounding the undoped semiconductor region, and forming a gate structure in the first and second gate openings and surrounding the nanostructured channel layer.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around FETs (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIGS. 1B and 1C illustrate cross-sectional views of a semiconductor device with a nanostructured channel structure, in accordance with some embodiments.

FIG. 2 is a flow diagram of a method for fabricating a semiconductor device with a nanostructured channel structure, in accordance with some embodiments.

FIGS. 3A-7B, 8A, 8B, 9A, 10A, and 10B illustrate cross-sectional views of a semiconductor device with a nanostructured channel structure at various stages of the fabrication process of FIG. 2, in accordance with some embodiments.

FIGS. 7C, 8C, and 9B illustrate germanium (Ge) concentration profiles across a nanostructured channel structure at various stages of the fabrication process, in accordance with some embodiments.

FIG. 9C illustrates variations in silicon germanium (SiGe) etch rates for different concentrations of Ge in a SiGe layer.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The present disclosure provides example multi-threshold voltage (Vt) devices with FETs (e.g., finFETs or GAA FETs) having improved nanostructured channel structure configurations. In some embodiments, the nanostructured channel structure includes a nanostructured channel layer with a silicon (Si) region and a germanium (Ge) doped region surrounding the Si region. In some embodiments, the nanostructured channel structure can include a capping layer surrounding the Ge doped region. Incorporating Ge atoms in nanostructured channel layer improves the performance of p-type FET (PFET) devices by inducing a higher compressive stress in the nanostructured channel layer. A higher compressive stress in a Ge infused nanostructured channel layer enhances carrier mobility and a higher ON current in PFET devices. Ge infused nanostructured channel layer provides better PFET Vth control in scaled down advanced device structures (e.g. finFETs or GAA FETs). The present disclosure also provides methods to form the nanostructured channel structure for scaled down device structures. The disclosed method particularly targets forming the Ge doped region and/or capping layer on the nanostructured channel layer for devices with a spacing constraint between adjacent nanostructured channel layers.

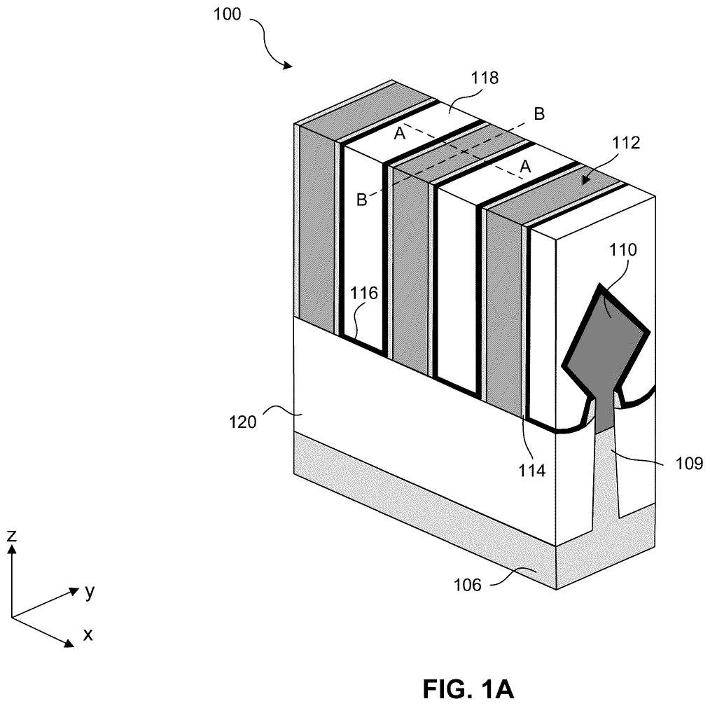

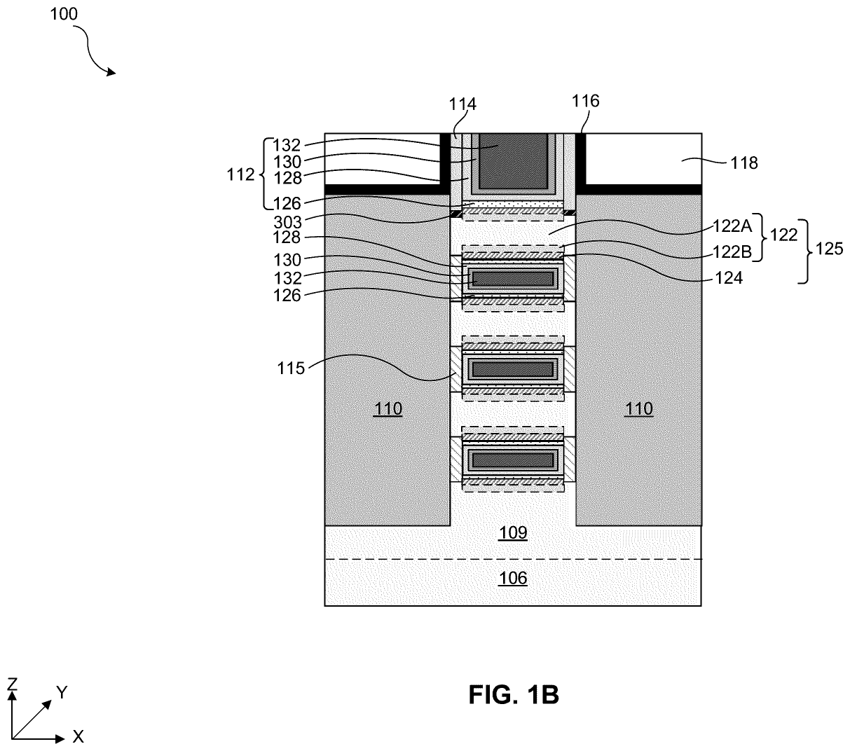

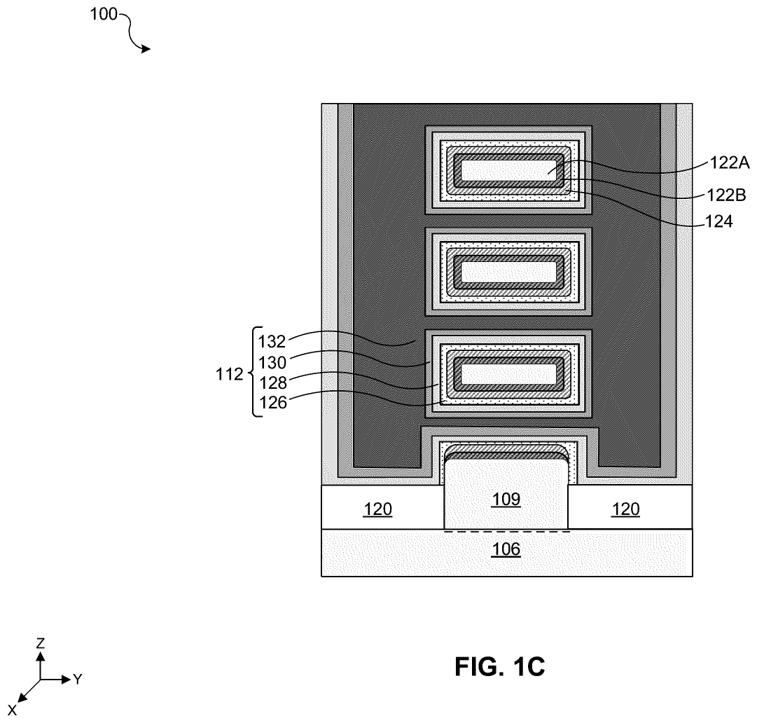

FIG. 1A illustrates an isometric view of a semiconductor device 100, according to some embodiments. In some embodiments, semiconductor device 100 can represent a FET 100. For example, FET 100 can be a GAA FET 100. In some embodiments, FET 100 can represent n-type FETs (NFETs) or PFETs. The discussion of FET 100 applies to both NFETs and PFETs, unless mentioned otherwise. FIG. 1B illustrates a cross-sectional view of FET 100 along line A-A of FIG. 1A, according to some embodiments. FIG. 1C illustrates a cross-sectional view of FET 100 along line B-B of FIG. 1A, according to some embodiments. FIGS. 1B and 1C illustrate cross-sectional views with additional structures that are not shown in FIG. 1A for simplicity. The discussion of elements in FIGS. 1A-1C with the same annotations applies to each other, unless mentioned otherwise.

Referring to FIGS. 1A-1C, FET 100 can include (i) a substrate 106, (ii) a fin base 109 (also referred to as a “sheet base 109”) (iii) gate structures 112 disposed on fin base 109, (iv) source/drain (S/D) regions 110 disposed on portions of fin base 109 that are not covered by gate structure 112, (v) nanostructured channel structures 125, (vi) gate spacers 114 disposed along sidewalls of gate structures 112, (vii) dielectric layer 303 beneath gate spacers 114, (viii) inner spacers 115 disposed along sidewalls of S/D regions 110, (vii) shallow trench isolation (STI) regions 120, (ix) etch stop layers (ESLs) 116 disposed directly on S/D regions 110, and (x) interlayer dielectric (ILD) layers 118 disposed directly on ESLs 116. S/D regions 110 may refer to a source or a drain, individually or collectively dependent upon the context. The term “nanostructured” refers to a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm are within the scope of the disclosure.

FET 100 can be formed on substrate 106. There may be other FETs and/or structures (e.g., isolation structures) formed on substrate 106. Substrate 106 can be a semiconductor material, such as Si, Ge, SiGe, a silicon-on-insulator (SOI) structure, other suitable semiconductor materials, and a combination thereof. Further, substrate 106 can be doped with p-type dopants (e.g., boron, indium, aluminum, or gallium) or n-type dopants (e.g., phosphorus or arsenic). In some embodiments, fin base 109 can include a material similar to substrate 106 and can have elongated sides extending along an X-axis. In some embodiments, STI regions 120, ESLs 116, and ILD layers 118 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), silicon germanium oxide (SiGeOₓ), and other suitable insulating materials.

Each nanostructured channel structure 125 can be surrounded by gate structure 112 and disposed on fin base 109. In some embodiments, each nanostructured channel structure 125 can include (i) a nanostructured channel layer 122, and (ii) a capping layer 124. In some embodiments, nanostructured channel layer 122 can include a semiconductor material, such as Si, silicon arsenic (SiAs), silicon phosphide (SiP), silicon carbide (SiC), silicon carbon phosphide (SiCP), and other suitable semiconductor materials.

In some embodiments, nanostructured channel layer 122 can include semiconductor regions 122A and 122B. In some embodiments, semiconductor region 122A can be Ge-free and can be an undoped semiconductor region 122A or a doped semiconductor region 122A. In some embodiments, semiconductor region 122A can be an undoped Si region 122A or a doped Si region 122A and can also be referred to as a “Si region 122A.” In some embodiments, doped Si region 122A can include non-Ge dopants, such as boron, indium, aluminum, or gallium dopants. In some embodiments, semiconductor region 122A can be surrounded by semiconductor region 122B. In some embodiments, semiconductor region 122B can be a doped semiconductor region 122B and can include Ge dopants. In some embodiments, semiconductor region 122B can be a Ge doped Si region 122B and can also be referred to as a “SiGe region 122B.” In some embodiments, a concentration of Ge atoms in semiconductor region 122B can be about 10 atomic % to about 40 atomic %.

In some embodiments, capping layer 124 can surround nanostructured channel layer 122 and can be in contact with semiconductor region 122B and gate structure 112. In some embodiments, capping layer 124 can include a Ge-based layer, such as SiGe, silicon germanium boron (SiGeB), germanium boron (GeB), silicon germanium stannum boron (SiGeSnB), and other suitable Ge-based layer. In some embodiments, capping layer 124 may not be present in nanostructured channel structure 125 and semiconductor region 122B of nanostructured channel layer 122 can be in contact with gate structure 112. Though three nanostructured channel structures 125 are shown in FET 100, FET 100 can include any number of nanostructured channel structures 125. Though rectangular cross-sections of nanostructured channel layer 122 are shown, nanostructured channel layer 122 can have cross-sections of other geometric shapes (e.g., circular, elliptical, triangular, or polygonal).

In some embodiments, for NFET 100, S/D regions 110 can include an epitaxially-grown semiconductor material, such as Si, and n-type dopants, such as phosphorus and other suitable n-type dopants. In some embodiments, for PFET 100, S/D regions 110 can include an epitaxially-grown semiconductor material, such as Si and SiGe, and p-type dopants, such as boron and other suitable p-type dopants.

Each gate structure 112 can be a multi-layered structure and can surround nanostructured channel structures 125, for which gate structure 112 can be referred to as “gate-all-around (GAA) structures” or “horizontal gate-all-around (HGAA) structures.” FET 100 can be referred to as “GAA FET 100.” Gate portions of gate structure 112 surrounding nanostructured channel structures 125 can be electrically isolated from adjacent S/D regions 110 by inner spacers 115, as shown in FIG. 1B. Gate portion of gate structure 112 disposed on top most nanostructured channel structure 125 can be electrically isolated from adjacent S/D regions 110 by gate spacers 114, as shown in FIG. 1B. Inner spacers 115 and gate spacers 114 can include an insulating material, such as SiO₂, SiN, SiON, SiCN, SiOCN, and other suitable insulating materials.

In some embodiments, each gate structure 112 can include (i) interfacial oxide (IL) layers 126, (ii) high-k (HK) gate dielectric layers 128, (iii) work function metal (WFM) layers 130, and (iii) gate metal fill layers 132. As used herein, the term “high-k (HK)” refers to a high dielectric constant. In the field of semiconductor device structures and manufacturing processes, HK refers to a dielectric constant that is greater than the dielectric constant of SiO₂ (e.g., greater than 3.9).

IL layers 126 can be disposed on and in contact with capping layers 124 of nanostructured channel structures 125. In the absence of capping layers 124, IL layers 126 can be disposed on and in contact with semiconductor regions 122B of nanostructured channel structures 125. In some embodiments, IL layers 126 can include SiO₂, SiGeOₓ, or germanium oxide (GeOₓ). HK gate dielectric layers 128 can be disposed on and in contact with IL layers 126. In some embodiments, HK gate dielectric layers 128 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium silicate (ZrSiO₂), zirconium aluminum oxide (ZrAlO), lanthanum oxide (La₂O₃), aluminum oxide (Al₂O₃), zinc oxide (ZnO), hafnium zinc oxide (HfZnO), and yttrium oxide (Y₂O₃).

WFM layers 130 can be disposed on HK gate dielectric layers 128. In some embodiments, WFM layers 130 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for NFET 100. In some embodiments, WFM layers 130 can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for PFET 100. In some embodiments, gate metal fill layer 132 can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

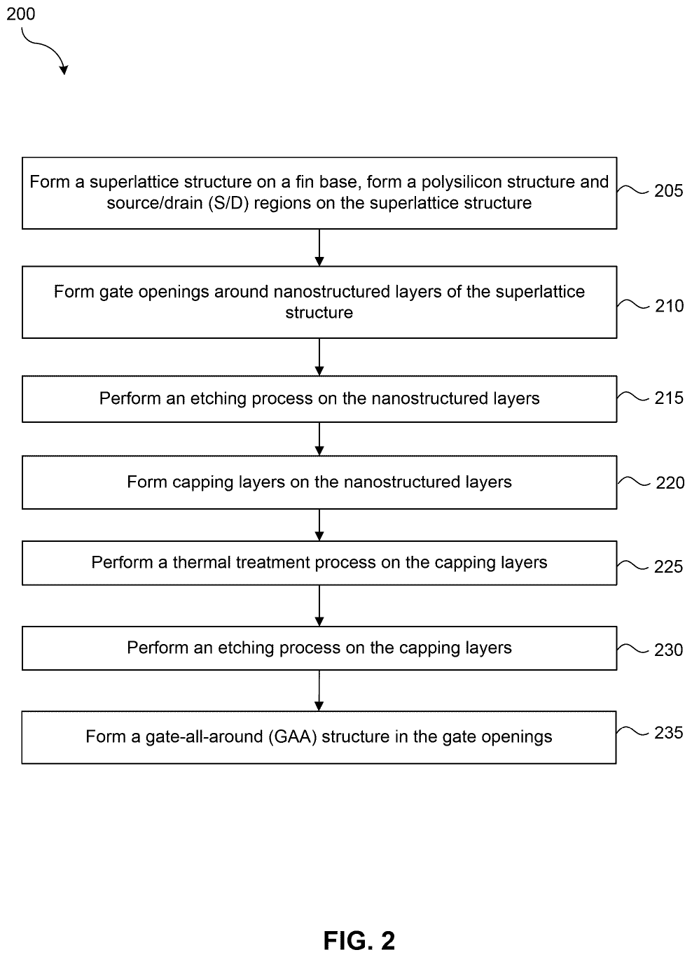

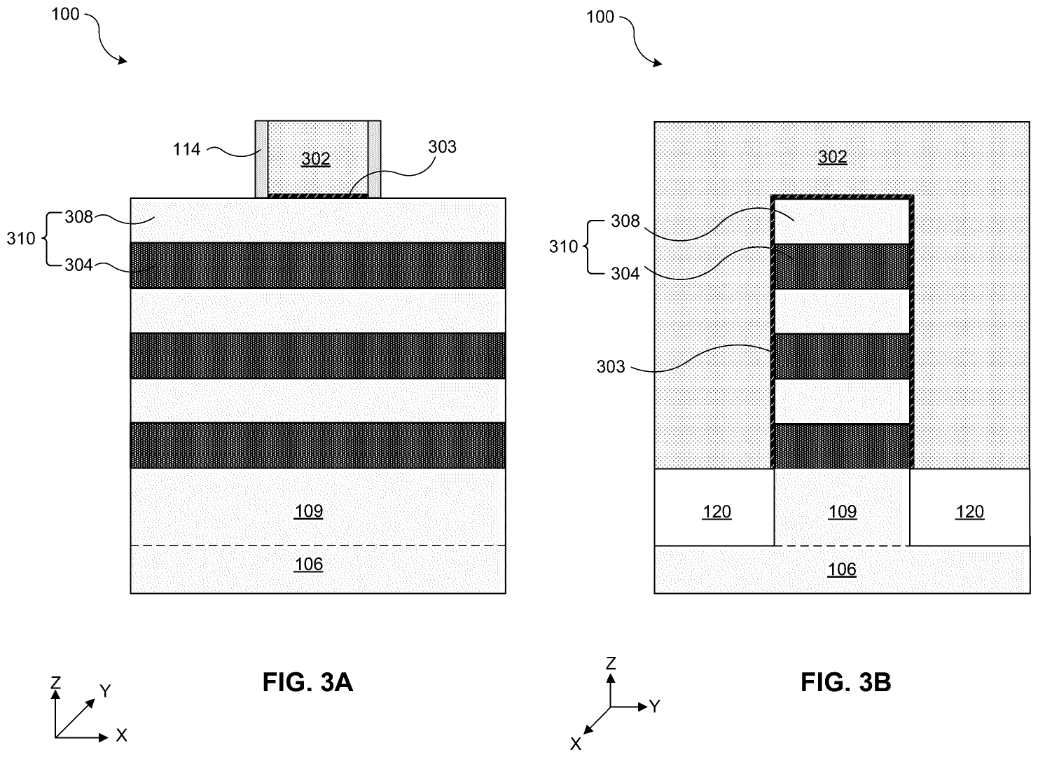

FIG. 2 is a flow diagram of an example method 200 for fabricating FET 100 as described above with reference to FIGS. 1A-1C, according to some embodiments. For illustrative purposes, the operations illustrated in FIG. 2 will be described with reference to the example fabrication process for fabricating FET 100 as illustrated in FIGS. 3A-7B, 8A, 8B, 9A, and 10A-11B, which are cross-sectional views of FET 100 along lines A-A and B-B of FIG. 1A at various stages of fabrication, according to some embodiments. Operations can be performed in a different order or not performed depending on specific applications. It should be noted that method 200 may not produce a complete FET 100. Accordingly, it is understood that additional processes can be provided before, during, and after method 200, and that some other processes may only be briefly described herein. Elements in FIGS. 3A-7B, 8A, 8B, 9A, and 10A-11B with the same annotations as elements in FIGS. 1A-1C are described above.

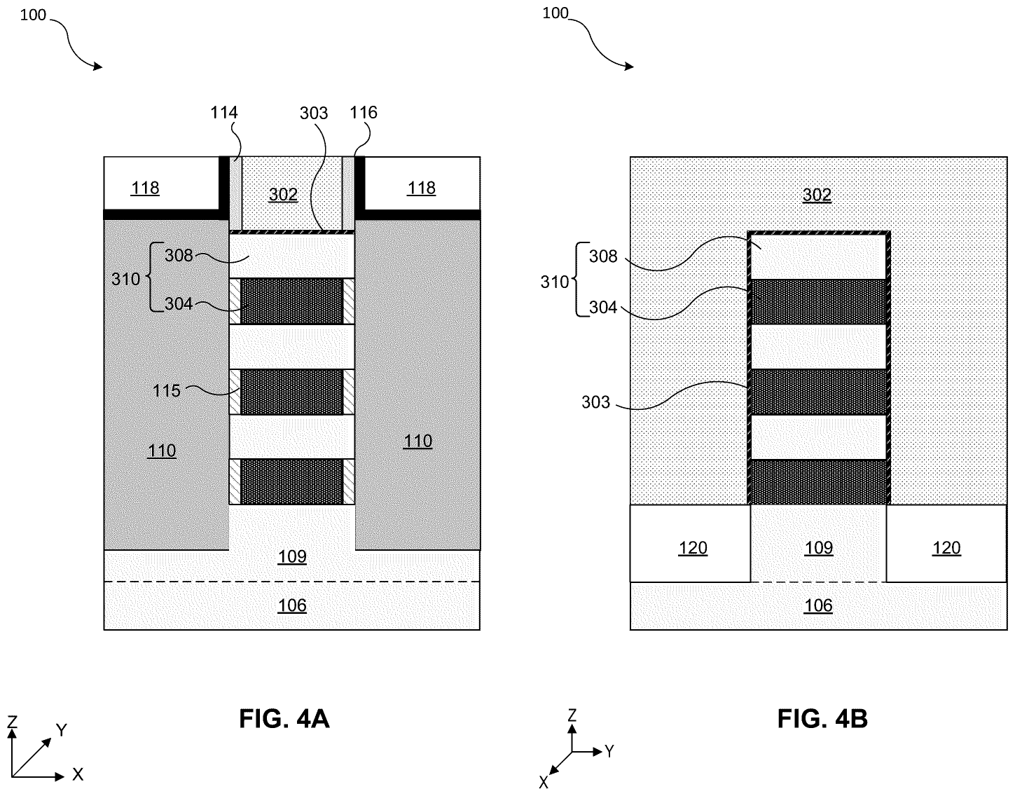

Referring to FIG. 2, in operation 205, a superlattice structure is formed on a fin base, and a polysilicon structure and S/D regions are formed on the superlattice structure. For example, as described with reference to FIGS. 3A-4B, a superlattice structure 310 (also referred to as “nanosheet stack 310”) can be epitaxially formed on fin base 109, and a polysilicon structure 302 and S/D regions 110 can be formed on superlattice structure 310. Superlattice structure 310 can include a sacrificial nanostructured layer 304 and a nanostructured layer 308 arranged in an alternating configuration. In some embodiments, nanostructured layer 308 can include materials similar to each other and sacrificial nanostructured layer 304 can include materials similar to each other. In some embodiments, each nanostructured layer 308 can have semiconductor materials similar to or different from substrate 106. In some embodiments, nanostructured layer 308 can include Si without any substantial amount of Ge (e.g., with no Ge) and sacrificial nanostructured layer 304 can include SiGe. During subsequent processing, polysilicon structure 302 and sacrificial nanostructured layers 304 can be replaced with gate structure 112 in a gate replacement process.

S/D regions 110 are formed on fin base 109 and on both sides of superlattice structure 310. S/D regions 110 can be either n-type S/D regions or p-type S/D regions. The formation of S/D regions 110 can include sequential operations of (i) forming S/D openings (not shown in the figure), through superlattice structure 310, on portions of fin base 109 that are not underlying polysilicon structure 302, as shown in FIGS. 4A and 4B, and (ii) epitaxially growing n-type or p-type semiconductor materials within S/D openings to form S/D regions 110, as shown in FIGS. 4A and 4B. In some embodiments, inner spacers 115 can be formed between operations (i) and (ii) of the formation process of epitaxial S/D regions 110, as shown in FIG. 4A. After the formation of S/D regions 110, ESLs 116 and ILD layers 118 can be formed on S/D regions 110 to form the structures of FIGS. 4A and 4B.

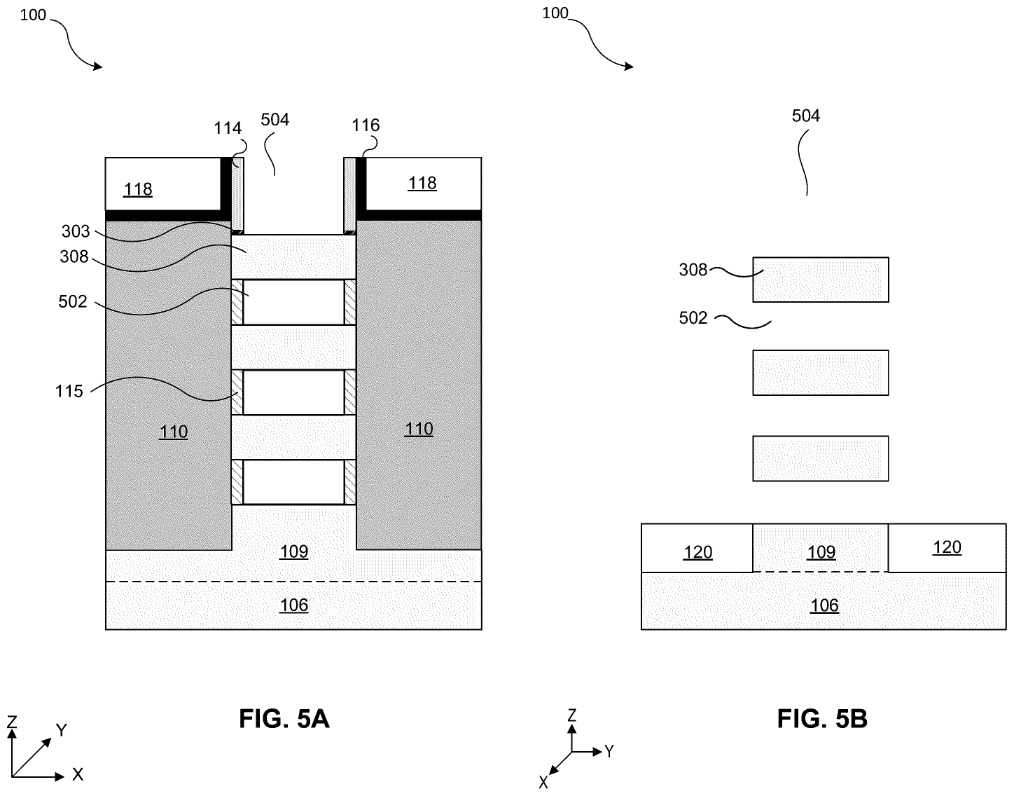

Referring to FIG. 2, in operation 210, gate openings are formed around nanostructured channel layers of the superlattice structure. For example, as described with reference to FIGS. 5A and 5B, gate openings 502 and 504 can be formed around nanostructured layers 308. Gate opening 504 can be formed by removing polysilicon structure 302. A dielectric layer 303 acts as an etch stop layer for removal of polysilicon structure 303 and prevents damage to an uppermost nanostructured layer 308. Gate openings 502 can be formed by removing dielectric layer 303 and sacrificial nanostructured layers 304. In some embodiments, sacrificial nanostructured layers 304 can be removed using a dry etch or a wet etch process. After removal of sacrificial nanostructured layers 304, nanostructured layers 308 are released and openings for the gate electrode are formed. During complete removal of sacrificial nanostructured layers 304, there may be some loss from nanostructured layers 308.

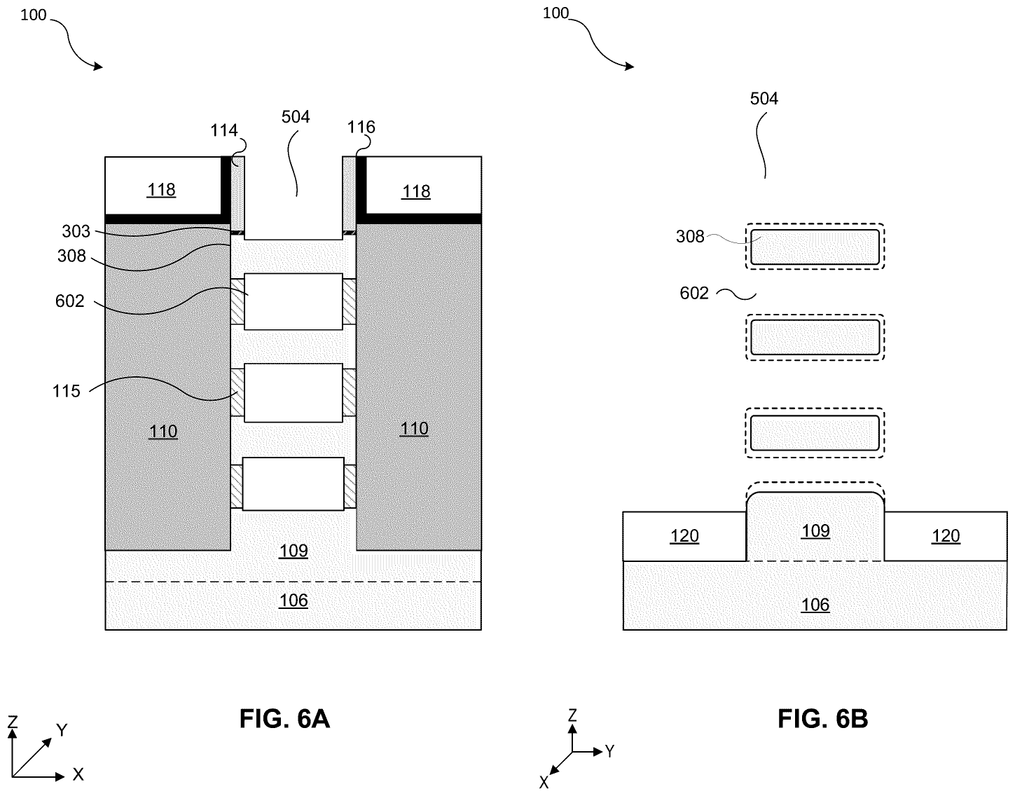

Referring to FIG. 2, in operation 215, in some embodiments, an etching process is performed on the nanostructured layers. For example, as described with reference to FIGS. 6A and 6B, an etching process can be performed on nanostructured layers 308. The etching process can isotropically remove a few nanometers of nanostructured layers 308 from all sides. The etching process may not trim nanostructured layers 308 under gate spacers 114, and under inner spacers 115. The etching process can modify gate openings 502 to create larger gate openings 602 between adjacent nanostructured layers 308 to (a) accommodate the deposition of capping layers on nanostructured layers 308 in subsequent operation, and (b) create a larger spacing for etching the capping layer in subsequent operations. Wet or dry etching techniques can be used for the etching process. For example, for nanostructured layers 308 composed of Si, about 2 nm to about 4 nm of Si can be isotropically removed during the etching process using a solution of ammonium hydroxide, hydrogen peroxide, and deionized (DI) water. The solution can also remove native oxide from nanostructured layers 308.

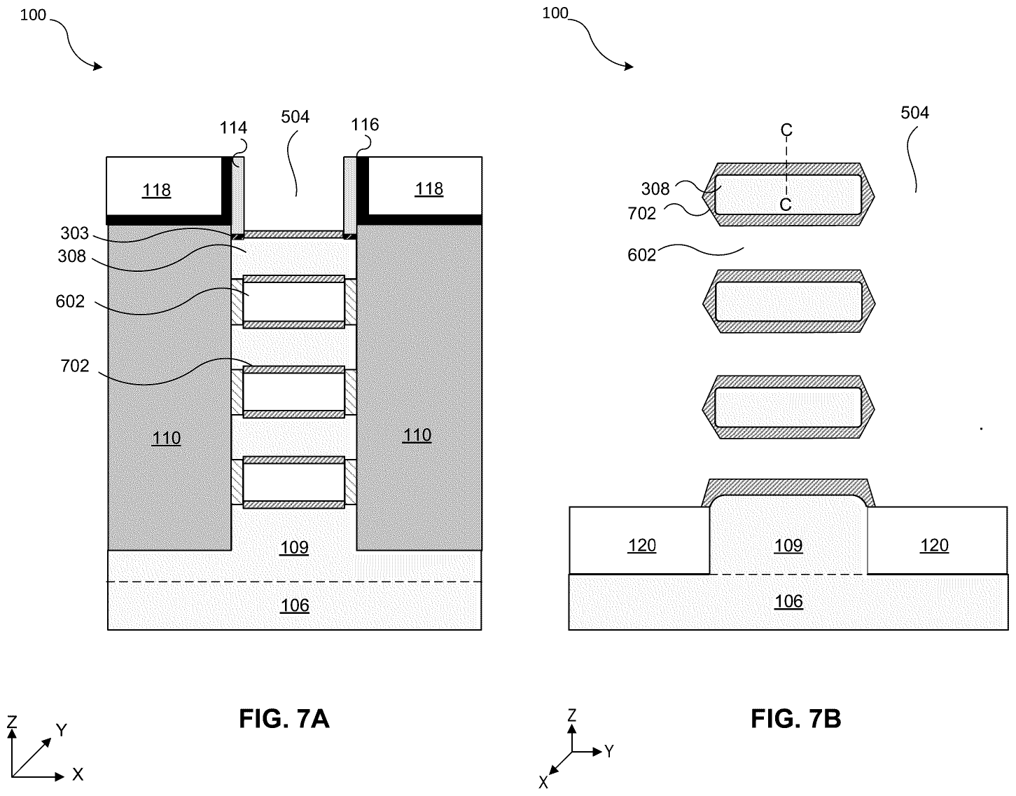

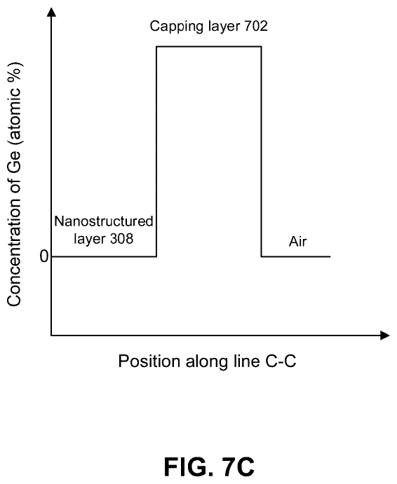

Referring to FIG. 2, in operation 220, capping layers are formed on the nanostructured layers. For example, as described with reference to FIGS. 7A-7C, capping layers 702 (e.g., SiGe capping layers 702) can be formed on nanostructured layers 308. In some embodiments capping layers 702 can be a germanium (Ge) based layer. In some embodiments, capping layers 702 can be homogeneous SiGe layer with a uniform distribution of Ge atoms. In some embodiments, each capping layer 702 can have a homogenous concentration of Ge of 25 atomic % to about 100 atomic %. Capping layer 702 can be selectively deposited on nanostructured layers 308 after the etching process of operation 215. In some embodiments, capping layers 702 can be deposited using a low pressure chemical vapor deposition (LPCVD) process. In some embodiments, the LPCVD process can be performed at a process pressure of less than about 100 torr and a temperature less than about 600° C. In some embodiments, the LPCVD process can use a hydrogen based or nitrogen based carrier gas. In some embodiments, silane (SiH₄) or dichlorosilane (SiH₂Cl₂) can be used as a precursor gas for Si and germane (GeH₄) can be used as a precursor gas for Ge when depositing capping layers 702. In some embodiments, a hydrogen chloride (HCl) etchant gas can be co-flowed with the precursor gases to promote a selective deposition process for depositing capping layers 702 around nanostructured layers 308. As illustrated in FIG. 7B, in some embodiments, capping layers 702 can have faceted surfaces due to lattice mismatch between capping layers 702 and nanostructured layers 308. In some embodiments, capping layers 702 and nanostructured layers 308 can have a Ge concentration profile across line C-C of FIG. 7B, as shown in FIG. 7C. In some embodiments, capping layers 702 can have a homogenous distribution of Ge atoms with a percentage Ge variation less than about 1 atomic % and Si nanostructured layers 308 can have zero concentration of Ge, as shown in FIG. 7C. The thickness of capping layer 702 depends on a spacing between adjacent nanostructured channel layers 122. For example, if a spacing between adjacent nanostructured channel layers 122 is in a range of about 4 nm to about 15 nm, then capping layer 702 can have a thickness in a range of about 2 nm to about 7 nm.

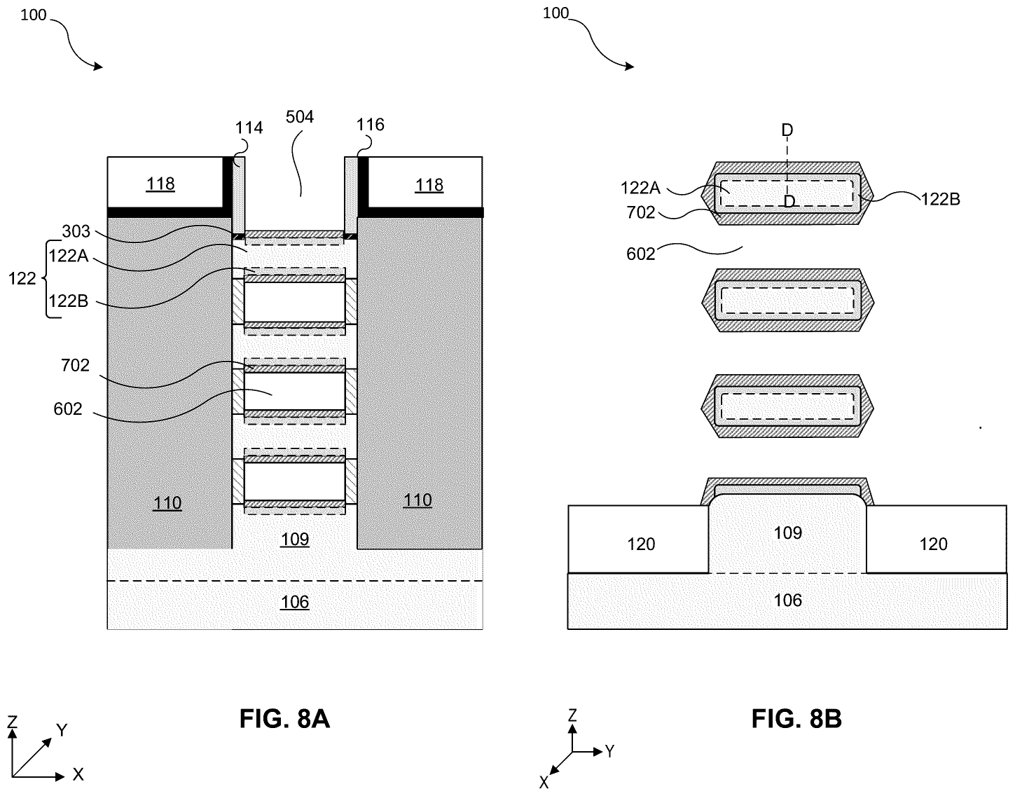

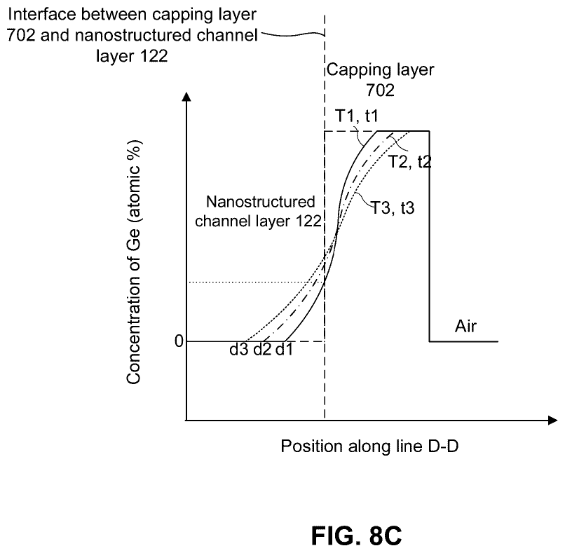

Referring to FIG. 2, in operation 225, a thermal treatment process is performed on the capping layers. For example, as described with reference to FIGS. 8A-8C, a thermal treatment process can be performed on capping layers 702 to convert nanostructured layers 308 to nanostructured channel layers 122. In some embodiments, the thermal treatment process can include using nitrogen or hydrogen as the carrier gas. In some embodiments, the thermal treatment process can be an in-situ process, immediately following the deposition of capping layers 702. In some embodiments, the thermal treatment process can be performed at a temperature of about 350° C. to about 650° C. for a duration time of about 200 seconds to about 600 seconds. In some embodiments, the temperature during the thermal treatment process can be ramped at about 3° C./sec or greater.

In some embodiments, nanostructured layers 308 can include Si. As a result of the thermal treatment process, portions of nanostructured layers 308 can be converted to SiGe. The thermal treatment process can diffuse Ge atoms from capping layers 702 into nanostructured layers 308 and form semiconductor regions 122B of nanostructured channel layers 122, as shown in FIGS. 8A and 8B. Therefore, semiconductor regions 122A (e.g., Si regions 122A) of nanostructured channel layers 122 can be surrounded by semiconductor regions 122B (e.g., SiGe regions 122B) of nanostructured channel layers 122 formed due to thermal diffusion of Ge from capping layers 702 to nanostructured layers 308. Semiconductor regions 122B can be surrounding by thermally treated capping layers 702, as shown in FIGS. 8A and 8B. In some embodiments, entire nanostructured layers 308 can be converted to SiGe by the thermal treatment process and both semiconductor regions 122A and 122B can have Ge atoms diffused from capping layers 702.

As illustrated in FIG. 7C, prior to the thermal treatment process, capping layers 702 can have a homogenous distribution or a uniform distribution of Ge atoms with a percentage Ge variation less than about 1 atomic %. The thermal treatment process can be a drive-in anneal process that drives the Ge atoms into nanostructured layers 308. The thermal treatment process can serve as a thermal assisted diffusion process for driving Ge atoms from capping layers 702 into nanostructured layers 308.

In some embodiments, the thermal treatment process can produce a distribution of Ge atoms across a thickness of capping layers 702 and nanostructured channel layers 122, as illustrated in FIG. 8C, which shows a Ge concentration profile across line D-D of FIG. 8B. The thermal treatment process can cause a reduction in concentration of Ge atoms in capping layers 702 close to interfaces between capping layers 702 and nanostructured channel layers 122. This can result in an increase in the concentration of the Ge atoms in nanostructured channel layers 122 close to the interfaces between nanostructured channel layers 122 and capping layers 702. The distribution of the Ge atoms across the thicknesses of capping layers 702 and nanostructured channel layers 122 can be controlled by controlling the temperature and duration of the thermal treatment process. A higher temperature and a longer thermal treatment process can produce a higher concentration of Ge atoms in semiconductor regions 122B of nanostructured channel layers 122. On the other hand, a lower temperature and a shorter thermal treatment process can produce a lower concentration of Ge atoms in semiconductor regions 122B of nanostructured channel layers 122. Additionally, the Ge concentration profile formed after the thermal treatment also depends on an initial thickness of capping layer 702.

As illustrated in FIG. 8C, the Ge concentration profile can be adjusted by adjusting the temperature and duration of the thermal treatment process. FIG. 8C shows that with an increase in temperature (T) and an increase in the duration (t) of the thermal treatment process, a Ge concentration profile with Ge diffusing to a greater depth within nanostructured channel layers 122 can be formed. The thermal treatment process parameters (temperature T₃, time t₃)>(temperature T₂, time t₂)>(temperature T₁, time t₁). As a result, the depth d₃ to which Ge diffuses at (T₃, t₃) is higher than the depth d₂ to which Ge diffuses at (T₂, t₂). Similarly, the depth d₂ to which Ge diffuses at (T₂, t₂) is higher than the depth d₁ to which Ge diffuses at (T₁, t₁).

In some embodiments, the thermal treatment process can result in a variation of Ge concentration across the thicknesses of capping layers 702 and semiconductor regions 122B of nanostructured channel layers 122, as illustrated in FIG. 8C. The concentration of Ge in the outer layers of capping layers 702 can be higher than the concentration of Ge in the inner layers of capping layers 702. The concentration of Ge can further reduce in portions of semiconductor regions 122B closer to semiconductor regions 122A of nanostructured channel layers 122. Such variations in Ge concentration across capping layers 702 and nanostructured channel layers 122 can be used to control the etch rate during the subsequent selective etching process used to completely or partially remove capping layers 702, as regions with a higher Ge concentration has a higher etch rate compared to regions with a lower Ge concentration. As a result, the etch rate of SiGe can reduce as the Ge concentration in capping layers 702 reduces from outer surfaces towards nanostructured channel layers 122. The SiGe etching process can have a higher etch selectivity to semiconductor regions 122A and semiconductor regions 122B of nanostructured channel layers 122 compared to capping layers 702.

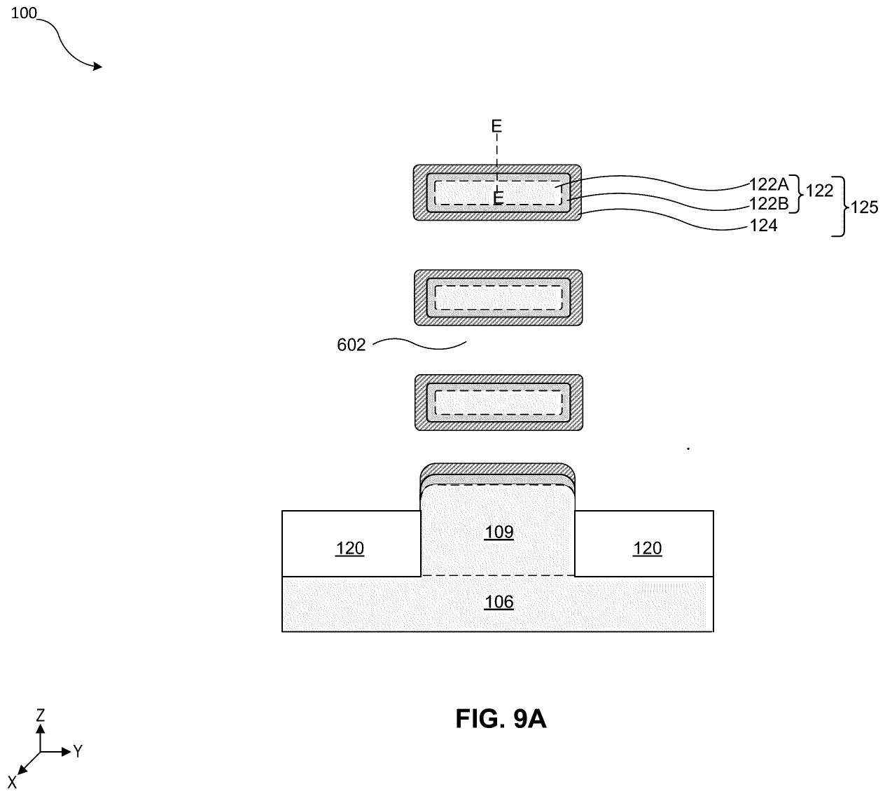

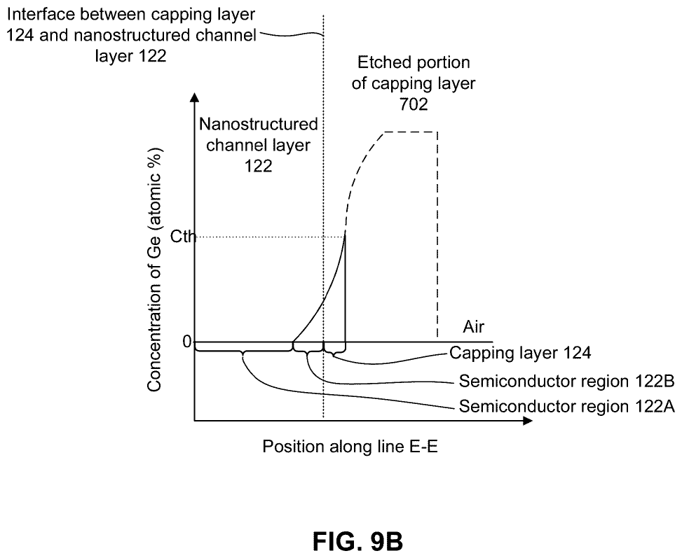

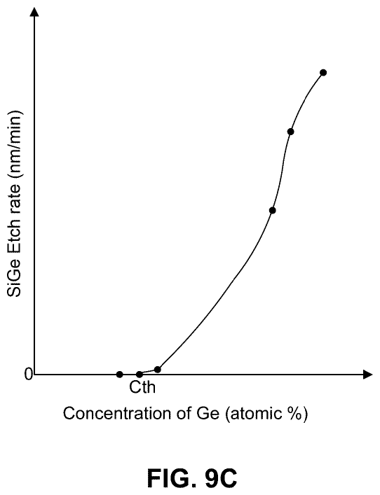

Referring to FIG. 2, in operation 230, an etching process is performed on the capping layers. For example, as described with reference to FIGS. 9A and 9B, an etching process can be performed on capping layers 702 to partially remove capping layers 702 to form capping layers 124 of nanostructured channel structures 125. In some embodiments, the etching process can completely remove capping layers 702. In some embodiments, the etching process can include a wet etch process. In some embodiments, the wet etch process can include using an etchant having an oxidizer, a fluorine-based etchant, and an inhibitor. In some embodiments, the oxidizer can be a peroxide or another oxidizer that can selectively oxidize Ge and can convert the Ge in capping layers 702 into germanium oxide (GeO₂), which is soluble in water. In some embodiments, the fluorine-based etchant can include at least one of, but not limited to, hydrofluoric acid (HF), buffered HF (BHF), or ammonium fluoride (NH₄F). In some embodiments, the inhibitor can include silanol to suppress Si removal and provide selectivity to Si. In some embodiments, the wet etch process can be used to achieve a Si:SiGe etch selectivity of about 1:40.

In some embodiments, the etching process in operation 230 can include a dry etch process using a fluorine-based gas. In some embodiments, the fluorine-based gas can include fluoride (F₂), HF, fluoroform (CHF₃), or methyl fluoride (CH₃F). These fluorine-based gases can react with Si to form silane tetrafluoride (SiF₄) and with Ge to form germanium tetrafluoride (GeF₄). The etch selectivity between SiGe and Si can be based on a bond energy difference between Si—Si bond, Si—Ge bond, and Ge—Ge bond. Since the Si—Si bond is stronger compared to the Si—Ge bond and the Ge—Ge bond, the dry etch process can selectively etch SiGe compared to Si of nanostructured channel layers 122. To further enhance etch selectivity between SiGe and Si, a lower processing temperature can be used.

FIG. 9B shows a Ge concentration profile across line E-E of FIG. 9A after etching capping layers 702 to form capping layers 124. As illustrated in FIG. 9B, the etching process can be terminated after detecting a threshold Ge concentration Cth across line E-E. As illustrated in FIG. 9B, at the end of the etching process, nanostructured channel structures 125 can have Si regions 122A and Ge doped regions 122B of nanostructured channel layers 122 and thermally treated capping layers 124. At a higher temperature (T), and duration (t) of the thermal treatment process, since the Ge can diffuse to a higher depth d₃, nanostructured channel structures 125 can have thinner Si regions 122A compared to thickness of Si regions 122A at lower temperature (T) and duration (t).

FIG. 9C shows variations in SiGe etch rate with respect to Ge concentrations in capping layers 702. As illustrated in FIG. 9C, the end point of the dry or wet etch process for etching SiGe capping layers 702 can be marked by a Ge concentration in capping layers for which the SiGe etch rate is about zero. The Ge concentration in capping layers 702 at which the etch rate is about zero can be referred to as the threshold Ge concentration Cth. The threshold Ge concentration Cth can be varied by varying the wet etch or dry etch parameters, where the etch parameters include mixing ratios of constituents comprising the etchant, processing temperature, and pH. The threshold Ge concentration Cth can be the percentage of Ge in the outer-most regions of capping layers 702 in contact with the etchant, at which the etch rate is substantially zero. For example, if the etching process has a threshold at about 25 atomic % of Ge, the outermost capping layers 702 at the end of the etch process can have about 25 atomic % of Ge. The etching process can be adjusted to have a different threshold Ge concentration Cth. For example, if the etching process can be adjusted to have a threshold at about 28 atomic % of Ge, the outermost regions of capping layers 702 at the end of the etching process can have about 28 atomic % of Ge. Therefore, the parameters of the etching process can determine the concentration of Ge in the outermost regions of capping layers 702. In some embodiments, at the end of the etching process, for an initial capping layer 702 thickness in a range of about 1 nm to about 3 nm, a combined thickness of Si regions 122A and Ge doped regions 122B can be between about 5 nm to about 10 nm. In some embodiments, thickness of Si region 122A can be equal to thickness of Ge doped region 122B.

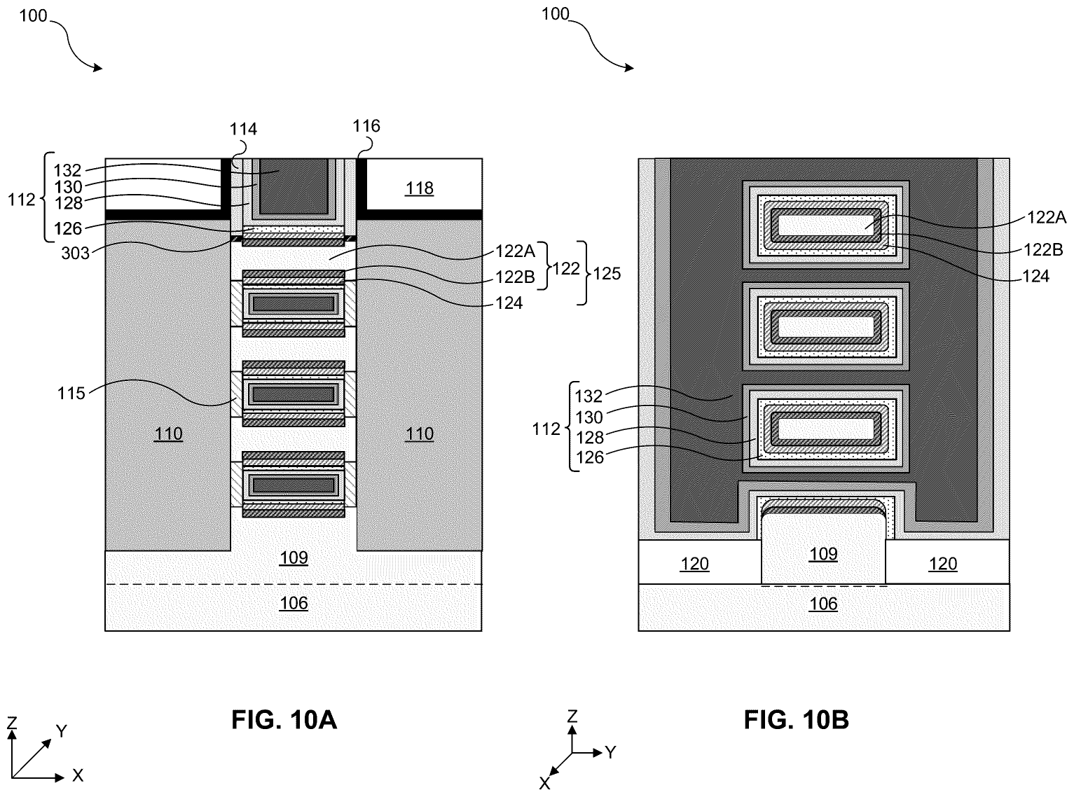

Referring to FIG. 2, in operation 235, a gate structure is formed in the gate openings. For example, as described with reference to FIGS. 10A and 10B, gate structure 112 can be formed in gate openings 504 and 602 surrounding nanostructured channel structures 125. The formation of gate structure 112 can include sequential operations of (i) forming IL layer 126 on nanostructured channel structures 125 (as shown in FIGS. 10A and 10B) or on nanostructured channel layers 122 if capping layers 124 absent (not shown), (ii) depositing HK gate dielectric layer 128 on IL layer 126, as shown in FIGS. 10A and 10B, (iii) depositing WFM layer 130 on HK gate dielectric layer 128, as shown in FIGS. 10A and 10B, (iv) depositing gate metal fill layer 132 on WFM layer 130, as shown in FIGS. 10A and 10B, and (v) performing a chemical mechanical polishing (CMP) process to coplanarize top surfaces of HK gate dielectric layer 128, WFM layer 130, gate metal fill layer 132 with respect to each other.

In some embodiments, IL layers 126 can be formed on exposed surfaces of capping layers 124 of nanostructured channel structures 125 within gate openings 502 and 504 or on exposed surfaces of semiconductor regions 122B of nanostructured channel layers 122 within gate openings 502 and 504 if capping layers 124 absent. In some embodiments, IL layers 126 can be formed by exposing capping layers 124 or semiconductor regions 122B to an oxidizing ambient. The oxidizing ambient can include a combination of ozone (O₃), a mixture of ammonia hydroxide, hydrogen peroxide, and water (“SC1 solution”), and/or a mixture of hydrochloric acid, hydrogen peroxide, water (“SC2 solution”).

In some embodiments, the deposition of HK gate dielectric layer 128 can include depositing a HK gate dielectric material on IL layers 126. In some embodiments, HK gate dielectric layer 128 can be formed with an ALD process using hafnium chloride (HfCl₄) as a precursor at a temperature ranging from about 250° C. to about 350° C. In some embodiments, the formation of HK gate dielectric layer 128 can be followed by an annealing process to improve the electrical characteristics and/or reliability of IL layers 126 and/or HK gate dielectric layer 128.

In some embodiments, the deposition of gate metal fill layer 132 can include depositing a fluorine-free metal layer (e.g., a FFW layer) within gate openings 502 and 504. The deposition of the fluorine-free metal layer can include depositing the fluorine-free metal layer with an ALD process using tungsten pentachloride (WCl₅) or Tungsten hexachloride (WCl₆) and H₂ as precursors at a temperature ranging from about 400° C. to about 500° C. In some embodiments, the fluorine-free metal layer can be deposited in an ALD process of about 160 cycles to about 320 cycles, where one cycle can include sequential periods of: (i) first precursor gas (e.g., WCl₅ or WCl₆) flow, (ii) a first gas purging process, (iii) a second precursor gas (e.g., H₂) gas flow, and (iv) a second gas purging process.

The present disclosure provides example multi-threshold voltage (Vt) devices with FETs (e.g., FET 100) having improved nanostructured channel structure configurations. In some embodiments, the nanostructured channel structure (e.g., nanostructured channel structure 125) includes a nanostructured channel layer (e.g., nanostructured channel layer 122) with a silicon (Si) region (e.g., semiconductor region 122A) and a germanium (Ge) doped region (e.g., semiconductor region 122B) surrounding the Si region. In some embodiments, the nanostructured channel structure can include a capping layer (e.g., capping layer 124) surrounding the Ge doped region. Incorporating Ge atoms in nanostructured channel layer improves the performance of p-type FET (PFET) devices by inducing a higher compressive stress in the nanostructured channel layer. A higher compressive stress in the Ge infused nanostructured channel layer enhances carrier mobility and a higher ON current in PFET devices. Ge infused nanostructured channel layer provides better PFET Vth control in scaled down advanced device structures (e.g. finFETs or GAA FETs). The present disclosure also provides methods (e.g., method 200) to form the nanostructured channel structure for scaled down device structures. The disclosed method particularly targets forming the Ge doped region and/or capping layer on the nanostructured channel layer for devices with a spacing constraint between adjacent nanostructured channel layers.

In some embodiments, a method includes forming a superlattice structure with a first nanostructured layer and a second nanostructured layer on a fin base, forming a polysilicon structure on the superlattice structure, removing the second nanostructured layer to form a first gate opening, removing the polysilicon structure to form a second gate opening, forming a capping layer on the first nanostructured layer, modifying the first nanostructured layer to form a nanostructured channel layer having an undoped semiconductor region and a doped semiconductor region surrounding the undoped semiconductor region, selectively etching an outer portion of the capping layer using an etching process with an etch selectivity based on concentration of germanium (Ge) in the capping layer, and forming a gate structure in the first and second gate openings and surrounding the nanostructured channel layer. An outermost region of the doped semiconductor region has a higher concentration of dopants than an innermost region of the doped semiconductor region.

In some embodiments, a method includes forming a capping layer on a nanostructured layer, annealing the capping layer to form a nanostructured channel layer having a Ge-free region and a Ge doped region, selectively etching an outer portion of the capping layer with a Ge concentration higher than a threshold Ge concentration to form a modified capping layer on the nanostructured channel layer, and forming a gate-all-around structure on the modified capping layer. A concentration of Ge atoms in the Ge doped region varies along a thickness of the Ge doped region.

In some embodiments, a semiconductor device includes a substrate, a fin base disposed on the substrate, a nanostructured channel structure disposed on the fin base, and a gate structure surrounding the nanostructured channel structure. The nanostructured channel structure includes a Ge-free region, a Ge doped region surrounding the Ge-free region, and a capping layer surrounding the Ge doped region. The Ge doped region includes a Ge concentration varying along a thickness of the Ge doped region.

What is claimed is:

1. A method, comprising:
forming a superlattice structure comprising a first nanostructured layer and a second nanostructured layer on a fin base;
forming a polysilicon structure on the superlattice structure;
removing the second nanostructured layer to form a first gate opening;
removing the polysilicon structure to form a second gate opening;
forming a capping layer on the first nanostructured layer;
modifying the first nanostructured layer to form a nanostructured channel layer comprising an undoped semiconductor region and a doped semiconductor region surrounding the undoped semiconductor region, wherein an outermost region of the doped semiconductor region has a higher concentration of dopants than an innermost region of the doped semiconductor region;
selectively etching an outer portion of the capping layer using an etching process with an etch selectivity based on concentration of germanium (Ge) in the capping layer; and
forming a gate structure in the first and second gate openings and surrounding the nanostructured channel layer.

2. The method of claim 1, wherein modifying the first nanostructured layer comprises doping an outer region of the first nanostructured layer with Ge atoms from the capping layer to form the doped semiconductor region.

3. The method of claim 1, further comprises etching a portion of the doped semiconductor region.

4. The method of claim 1, wherein forming the capping layer comprises epitaxially growing a silicon germanium (SiGe) layer on the first nanostructured layer.

5. The method of claim 1, further comprising etching an outer portion of the capping layer using an etchant comprising an oxidizer, a fluorine-based etchant, and a silicon inhibitor.

6. The method of claim 1, wherein modifying the first nanostructured layer comprises doping an outer region of the first nanostructured layer with Ge atoms from the capping layer to form the doped semiconductor region.

7. The method of claim 1, further comprising etching the capping layer to expose a surface of the doped semiconductor region.

8. The method of claim 1, further comprising etching the capping layer to form a modified capping layer surrounding the doped semiconductor region.

9. A method, comprising:
forming a capping layer on a nanostructured layer;
annealing the capping layer to form a nanostructured channel layer comprising a germanium (Ge)-free region and a Ge doped region, wherein a concentration of Ge atoms in the Ge doped region varies along a thickness of the Ge doped region;
selectively etching an outer portion of the capping layer with a Ge concentration higher than a threshold Ge concentration to form a modified capping layer on the nanostructured channel layer; and
forming a gate-all-around structure on the modified capping layer.

10. The method of claim 9, wherein annealing the capping layer comprises annealing the nanostructured layer at a temperature of about 550° C. to about 650° C.

11. The method of claim 9, further comprising forming the nanostructured channel structure with a predetermined thickness by controlling:
a duration and temperature of annealing; and
at least one of a composition of a SiGe etchant, a pH, or a temperature during the selective etching of the outer portion of the capping layer.

12. The method of claim 11, wherein controlling the composition of the SiGe etchant comprises controlling a mixing ratio of an oxidizer, a fluorine-based etchant, and an inhibitor.

13. The method of claim 9, wherein forming the gate-all-around structure comprises oxidizing top surfaces of the modified capping layer.

14. The method of claim 9, wherein forming the gate-all-around structure comprises oxidizing top surfaces of the Ge doped region.

15. The method of claim 9, wherein selectively etching the capping layer comprises removing a plurality of facets of the capping layer.

16. A semiconductor device, comprising:
a substrate;
a fin base disposed on the substrate;
a nanostructured channel structure, disposed on the fin base, comprising:
a germanium (Ge)-free region,
a Ge doped region surrounding the Ge-free region, wherein the Ge doped region comprises a Ge concentration varying along a thickness of the Ge doped region;
a capping layer surrounding the Ge doped region; and
a gate structure surrounding the nanostructured channel structure.

17. The semiconductor device of claim 16, wherein the capping comprises a silicon germanium (SiGe) layer.

18. The semiconductor device of claim 16, wherein the Ge-free region comprises a Ge-free silicon region.

19. The semiconductor device of claim 16, wherein the Ge concentration in the Ge doped region is lower than a Ge concentration in the capping layer.

20. The semiconductor device of claim 16, wherein the Ge doped region is in contact with the gate structure.
